(19) United States
(12) Patent Application Publication
(10) Pub. No.: US 2018/0374329 A1
(43) Pub. Date: Dec. 27, 2018

(54) FLEXIBLE TRANSMISSION LINE PRESSURE SENSOR

(71) Applicant: Massachusetts Institute of Technology, Cambridge, MA (US)

(72) Inventors: Matthew Eric D'Asaro, Cambridge, MA (US); Jeffrey H. Lang, Sudbury, MA (US)

(73) Assignee: Massachusetts Institute of Technology, Cambridge, MA (US)

(21) Appl. No.: 16/065,520

(22) PCT Filed: Dec. 30, 2016
(86) PCT No.: PCT/US2016/069389

§ 371 Date: Jun. 22, 2018

Related U.S. Application Data
(60) Provisional application No. 62/272,745, filed on Dec. 30, 2015.

(51) Int. Cl. G08B 13/26; G08B 21/04; G08B 25/10; H03K 17/955

(52) U.S. Cl. CPC G08B 13/26; H03K 17/955; G08B 25/10; G08B 21/0453

(57) ABSTRACT

A sensing apparatus includes a transmission line sensor and an electronics module. The transmission line sensor includes a first conductor, a second conductor and a dielectric between the first conductor and the second conductor. The electronics module is configured to transmit a first signal along the transmission line sensor, receive a second signal from the transmission line sensor, and analyze the second signal to determine information regarding deformation of the transmission line sensor caused by a force applied to the transmission line sensor.

### CROSS-REFERENCE TO RELATED APPLICATIONS

This application is a national stage application under 35 U.S.C. § 371 of International Patent Application Serial No. PCT/US2016/069389, filed on Dec. 30, 2016, entitled “FLEXIBLE TRANSMISSION LINE PRESSURE SENSOR,” which claims priority to U.S. provisional application Ser. No. 62/272,745, filed Dec. 30, 2015, titled “Tactile Sensor Based on Microwave Transmission Line,” which are hereby incorporated by reference in their entirety.

### FEDERALLY SPONSORED RESEARCH

This invention was made with Government support under Grant No. EEC-1028725 awarded by the National Science Foundation. The Government has certain rights in the invention.

### BACKGROUND

### 1. Technical Field

The techniques described herein relate generally to sensors, and in particular to a flexible, distributed transmission line pressure sensor suitable for a variety of applications such as tactile sensing and pressure monitoring, by way of example and not limitation.

### 2. Discussion of the Related Art

Over the past decade there have been numerous publications on tactile sensors and skins aimed at replicating the human sense of touch in applications such as robotics, healthcare, and prosthetics. A variety of sensing approaches are used, with the dominant ones being piezoresistive and capacitive.

### SUMMARY

Some embodiments relate to an apparatus that includes a transmission line sensor and an electronics module. The transmission line sensor includes a first conductor, a second conductor and a dielectric between the first conductor and the second conductor. The electronics module is configured to transmit a first signal along the transmission line sensor, receive a second signal from the transmission line sensor, and analyze the second signal to determine information regarding deformation of the transmission line sensor caused by a force applied to the transmission line sensor.

The transmission line sensor may be mechanically flexible and/or stretchable.

Some embodiments relate to a transmission line sensor that is mechanically flexible and/or stretchable. The transmission line sensor includes a first conductor, a second conductor, and a dielectric between the first conductor and the second conductor, the dielectric being compressible in response to an applied force to cause a change in impedance at a location at which the dielectric is compressed that reflects an incident electrical signal in a frequency range of 1 kHz to 300 GHz.

Some embodiments relate to a method of operating a sensing apparatus comprising a transmission line sensor, the transmission line sensor including, a first conductor, a second conductor, and a dielectric between the first conductor and the second conductor. The method includes transmitting a first signal along the transmission line sensor, receiving a second signal from the transmission line sensor in response to the first signal, and analyzing the second signal to determine information regarding deformation of the transmission line sensor caused by a force applied to the transmission line sensor.

Some embodiments relate to an apparatus that includes a transmission line sensor that is mechanically flexible and/or stretchable, the transmission line sensor including a transmission line. The transmission line sensor also includes an electronics module configured to: transmit a first signal along the transmission line sensor; receive a second signal from the transmission line sensor; and analyze the second signal to determine information regarding deformation of the transmission line sensor caused by a force applied to the transmission line sensor.

The foregoing summary is provided by way of illustration and is not intended to be limiting.

### BRIEF DESCRIPTION OF THE DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 shows a diagram of a sensing apparatus, according to some embodiments.

FIG. 2 shows a top view of a transmission line sensor, according to some embodiments.

FIG. 3 shows a cross sectional view of the transmission line sensor of FIG. 2.

FIG. 4 shows an equivalent circuit representation of a portion of the sensing apparatus including the transmission line sensor, according to some embodiments.

FIG. 5 shows a cross sectional view of a transmission line sensor having a signal conductor between two ground planes, according to some embodiments.

FIG. 6 shows a top view of a transmission line sensor that can be used to measure shear force, according to some embodiments.

FIG. 7A-C show cross sectional views of the transmission line sensor of FIG. 6 with different forces applied.

FIG. 8 shows a diagram illustrating the sensing apparatus providing an output to an actuator that can stimulate a sense of touch.

FIG. 9 shows a diagram illustrating the sensing apparatus providing an output to an indicator device.

FIG. 10 shows a transmission line sensor being worn on a finger.

FIG. 11 shows a transmission line sensor wearable on a palm.

FIG. 12 shows bedding with incorporated transmission line sensors.

FIG. 13 shows a prosthetic with a liner having an incorporated transmission line sensor.

FIG. 14 a-d show a method of forming a transmission line sensor as shown in FIGS. 2 and 3.

FIG. 15 shows a plot illustrating the reconstructed line depression when the sensor of FIGS. 2 and 3 is depressed by various amounts at various line positions.

FIG. 16 a-e show a method of forming a transmission line sensor as shown in FIG. 5.

FIG. 17 shows a plot illustrating the reconstructed line depression when the sensor of FIG. 5 is depressed by various amounts at various line positions.

FIG. 18 shows a plot illustrating the reconstructed line depression when the sensor of FIG. 5 is depressed by 300 microns when the sensor is flat and when the sensor is knotted.

FIG. 19 is a plot showing a resolution measurement.

FIG. 20 shows a two-dimensional transmission line sensor, according to some embodiments.

### DETAILED DESCRIPTION

Prior tactile sensors and skins aimed at replicating the human sense of touch use arrays of discrete sensors. Connections need to be made to each sensor in the array, and as the number of sensors increases, the number of connections needed is at least 2√N, where N is the number of sensors. To increase the spatial resolution, a larger number of sensors N is needed. However, this leads to the need for a large number of connections, which can be challenging to manufacture, and thus expensive. Accordingly, the inventors have recognized and appreciated that it would be desirable to avoid the need for a large number of connections.

Further, the inventors have recognized and appreciated the need for improved durability. In flexible and/or stretchable devices, making the interconnections and reliably connecting rows and columns to external electronics can present manufacturing challenges. Furthermore, such arrays are intrinsically fragile, as damaging a single device may disable an entire row and/or column of sensors, and the sensors themselves are fragile.

Described herein is a flexible transmission line sensor that is durable and does not require a large number of connections. In some embodiments, the flexible transmission line sensor is a distributed sensor, as opposed to an array of discrete sensors. The flexible transmission line sensor may include flexible conductors separated by a flexible, compressible dielectric. The flexible transmission line sensor may be disposed on an article of clothing worn on the human body, such as a glove, or a prosthetic liner, for example. Applied pressure may compress a region of the flexible transmission line sensor which may cause a change in the impedance of the transmission line. The change in impedance can be sensed by exciting the transmission line using an electrical signal and measuring the reflected signal. Examples of suitable techniques include time domain reflectometry (TDR) and frequency domain reflectometry (FDR). By measuring the delay (e.g., time delay or phase delay) of the reflected signal, the position of the applied pressure can be determined. By measuring the magnitude of the reflected signal, the magnitude of the applied pressure may be determined. Accordingly, both the location and the magnitude of the applied pressure can be measured. Advantageously, forces applied at a plurality of positions along the transmission line sensor may be detected at the same time by measuring multiple reflections.

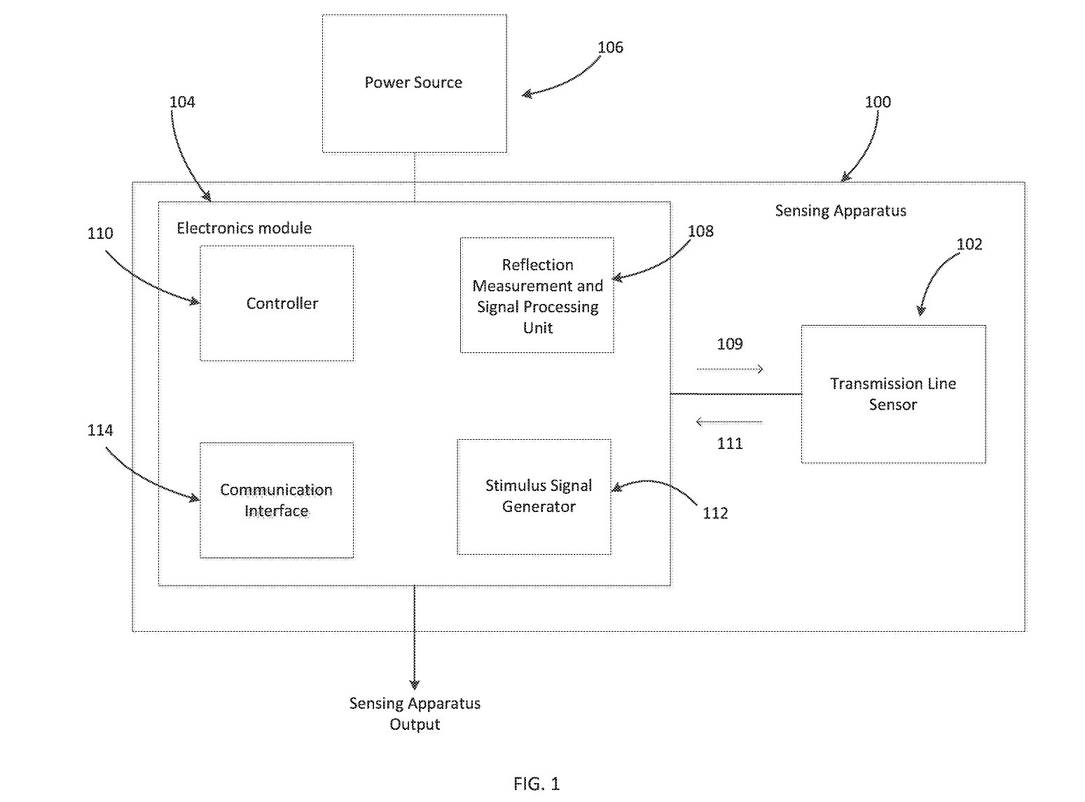

FIG. 1 shows an embodiment of a sensing apparatus 100. The sensing apparatus 100 may include a transmission line sensor 102 and an electronics module 104. Transmission line sensor 102 and electronics module 104 are electrically connected to one another. Transmission line sensor 102 may be a distributed sensor that can be disposed in a location at which force, pressure, or a related physical parameter is desired to be measured.

Electronics module 104 may include circuitry for stimulating transmission line sensor 102 and measuring signals received from transmission line sensor 102. The electronics module 104 may include a reflection measurement and signal processing unit 108, a controller 110, and a stimulus signal generator 112. The stimulus signal generator 112 may include circuitry that generates a stimulus signal 109 to stimulate the transmission line sensor 112. The stimulus signal 109 may include pulses and/or continuous waveforms. In response to the stimulus signal 109, the transmission line sensor 102 produces a response signal 111. The response signal 111 may include pulses and/or a continuous waveform depending on the content of stimulus signal 109. The reflection measurement and signal processing unit 108 receives the response signal 111 and processes the response signal to determine information regarding the deformation of the transmission line sensor 102. For example, the reflection measurement and signal processing unit 108 may calculate the position and/or magnitude of the deformation of the transmission line sensor 102. Since the speed of a signal propagating on a transmission line is constant, the distance to the deformation on the transmission line may be calculated based upon the time delay between the time the stimulus signal 109 is sent and the time response signal 111 is received. In the case of a continuous waveform, such as a sinusoidal waveform, for example, the distance to a deformation may be calculated based upon the phase delay between the stimulus signal 109 and the response signal 111. The transmission line sensor 102 may be stretchable. In some embodiments, the amount of stretch or elongation of the transmission line sensor 102 may be measured based upon a time or phase delay in the response signal 111.

The controller 110 may control the operation of the electronics module 104 and the transmission line sensor 102. In some embodiments, one or both of the stimulus signal generator 112 and the reflection measurement and signal processing unit 108 may be part of the controller 110.

Sensing apparatus 100 may receive power from a power source 106, which may be any suitable power source such as a mobile power source (e.g., a battery or wireless power receiver) or a fixed power source (e.g., a power adapter).

The electronics module 104 may provide an output, which may include information sensed by the sensing apparatus 100, such as information regarding the position and/or magnitude of the deformation sensed by transmission line sensor 102. Such information may be representative of any physical parameter sensed by transmission line sensor 102, such as force, pressure or amount of deformation (e.g., compression, shear displacement, or elongation) of the transition line sensor, by way of example. Depending on the application in which the sensing apparatus 100 is used, this information may be provided to a clinician or patient for appropriate action to be taken, such as adjusting a prosthetic, modifying the patient's position, etc. As another example, the information may be used to stimulate a sensation in a person to create a sense of touch. For example, if the transmission line sensor 102 is worn on a glove, information regarding the position and/or magnitude of the sensed deformation may be provided to an actuator that stimulates the wearer's sense of touch. Examples of suitable actuators include vibrational actuators, electrical stimulators, neural implants, etc. Any such outputs may be provided via a communication interface 114, which may include suitable wired or wireless communication circuitry. The possible sensing apparatus outputs is in no way limited to the examples given.

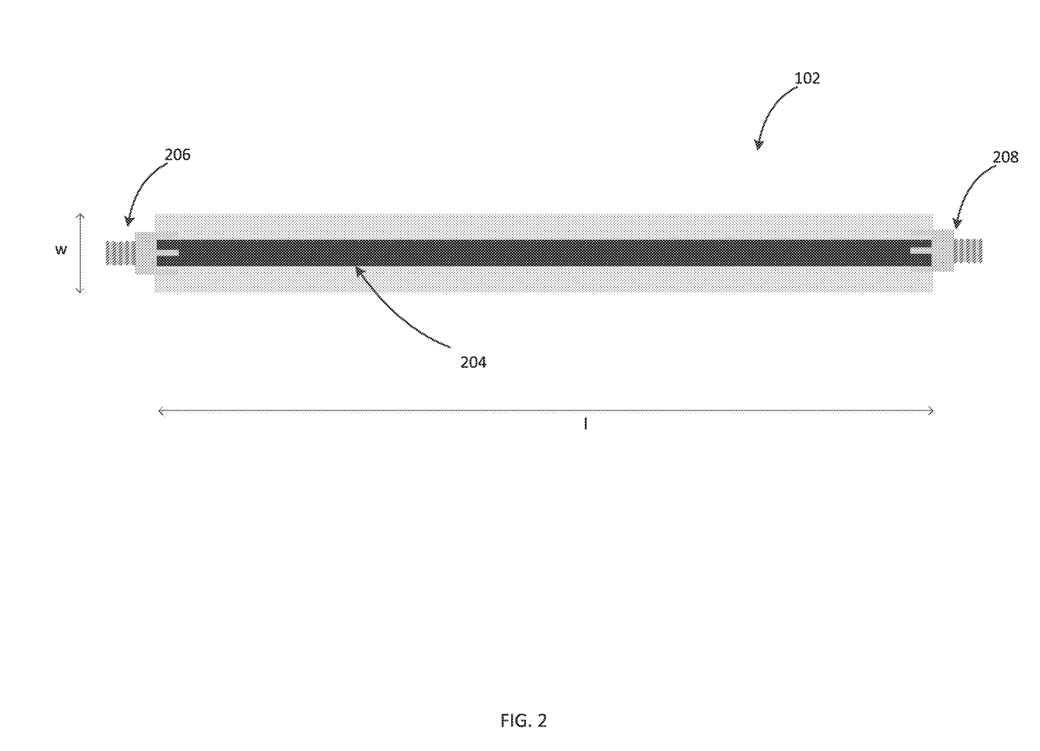

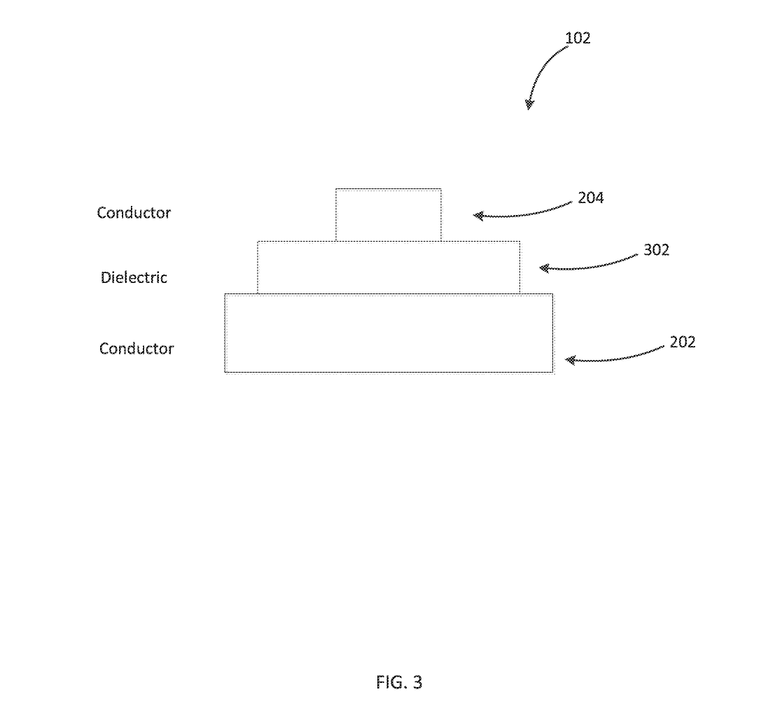

FIG. 2 shows a top view of an embodiment of the transmission line sensor 102. FIG. 3 shows a cross-sectional view of the transmission line sensor 102 of FIG. 2. As shown in FIG. 3, transmission line sensor 102 includes a transmission line formed by conductors 202 and 204 and a dielectric 302 that separates conductors 202 and 204. In some embodiments, conductor 202 may be a ground plane. In some embodiments, conductor 204 may have a smaller width than conductor 202. However, the techniques described herein are not limited in these respects.

Returning to a discussion of FIG. 2, the transmission line sensor 102 may include a connector 206. Connector 206 may connect the transmission line sensor 102 to the electronics module 104. Any suitable type of connector may be used. The transmission line sensor 102 may also include a termination or a connector for a termination 208. Termination connector 208 may be connected to any suitable component for terminating the transmission line with a suitable impedance. As shown in FIG. 2, the transmission line sensor 102 may have a length 1 that is much larger than its width. In some embodiments, the ratio 1/w may be greater than 5, greater than 10, greater than 15, greater than 20, or even greater, and in some cases may be less than 1,000. In some embodiments, the length 1 may be between 1 cm and 100 cm, such as between 5 cm and 50 cm, or between 10 cm and 30 cm (e.g., 20 cm). The width w may be any suitable width, and in some embodiments the width may be chosen based on the desired impedance of the transmission line. In some embodiments, the width w may be between 0.1 cm and 100 cm, such as between 0.5 cm and 10 cm, or between 0.5 cm and 5 cm, such as between 1 cm and 2 cm(e.g., 1.3 cm). In some embodiments, the thickness may be between 0.1 mm and 5 mm, such as between 0.5 mm and 3 mm (e.g., 1.6 mm).

As discussed above, in some embodiments the transmission line sensor 102 may be configured to be worn on an article such as a glove or a prosthetic liner. Accordingly, in some embodiments the transmission line sensor 102 may have substantial mechanical flexibility and/or stretchability. The mechanical flexibility may be similar to that of materials used for articles of clothing, to enable the article to move along with the wearer. The transmission line sensor 102 may be easily folded over on itself by hand. Accordingly, conductors 202 and 204 and dielectric 302 each may have substantial mechanical flexibility.

In some embodiments, dielectric 302 may be formed of a flexible insulating material. In some embodiments, the dielectric 302 may be stretchable and/or compressible. In some embodiments, the dielectric material 302 may include a silicone rubber such as Polydimethylsiloxane (PDMS), or NuSil® R-2188. The dielectric may include an added a high-κ ceramic material such as CaCu3Ti4O12 (CCTO), increasing sensor resolution. However, the dielectric 302 is not limited to any particular materials. Desirable properties for the dielectric material are: flexibility; stretchability, squishability, i.e., an appropriate low Young's modulus (where appropriate means a good match to the force to be measured); high electrical resistivity and as high an electrical permittivity as possible. In some embodiments, the Young's modulus may be less than 10 MPa, such as less than 1 MPa, and greater than 1 KPa, such as greater than 50 or 100 KPa.

Conductors 202 and 204 may be formed of any suitable flexible material. In some embodiments, conductors 202 and/or 204 may be formed of conductive cloth, conductive polymers, such as silicone rubber with added conductive particles, thin layers of metal such as, but not limited to, evaporated gold, or liquid metal such as gallium contained in a channel of polymer such as silicone rubber. However, the conductors 202 and 204 are not limited as to particular materials.

The transmission line sensor may be elastically deformable. That is, it may deform in response to an applied force (e.g., compressive, shear or elongation), and then may return to its original shape once the applied force is no longer present. Each of the conductors and the dielectric may be elastically deformable.

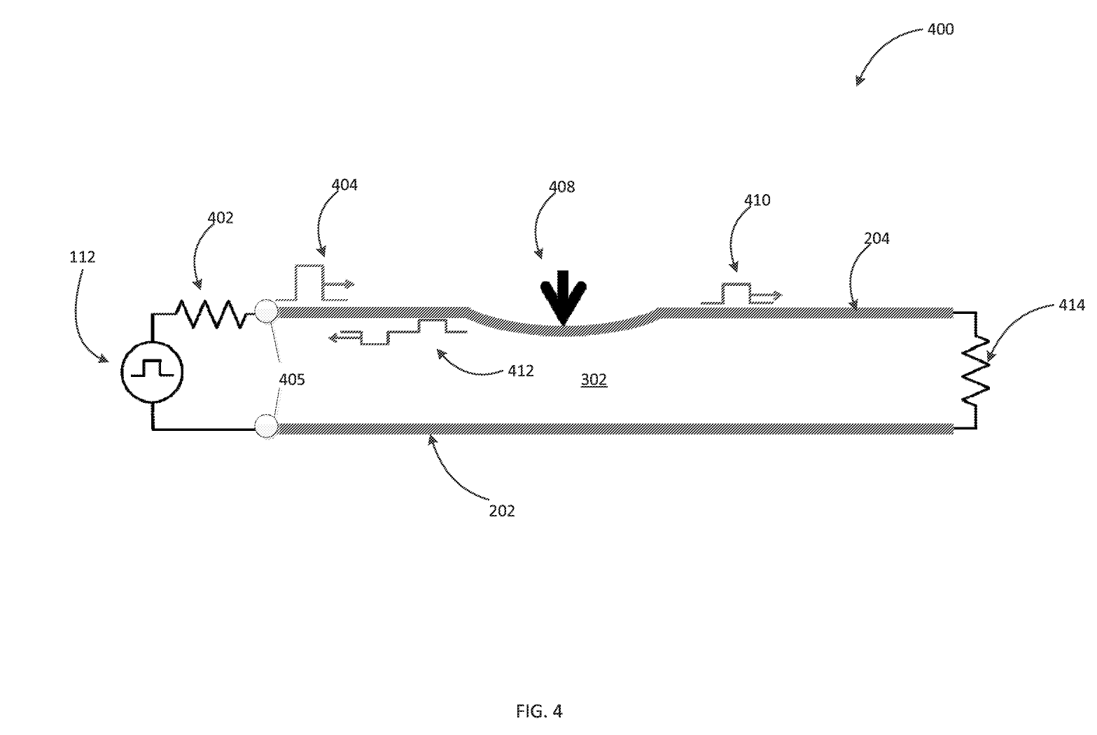

FIG. 4 shows an equivalent circuit diagram 400 for a portion of the sensing apparatus 100. FIG. 4 illustrates an example in which the stimulus signal 109 includes a pulse 404 generated by the stimulus signal generator 112. The forward pulse 404 may be applied to an input terminal 405 of the transmission line. A force 408 may be applied at a location along the length of the transmission line sensor 102 in a direction perpendicular to the conductor s 202 and 204. The dielectric 302 compresses in response to the force 408. While the force 408 is shown as being applied to the first conductor 204, it should be noted that the force 408 could be applied to the second conductor 202, alternatively or additionally. The force 408 changes the local impedance of the transmission line by increasing the capacitance and decreasing the inductance at that point. The change in local impedance may cause the forward pulse 404 to split into a reflected pulse 412 and a transmitted pulse 410 at the location along the transmission line at which the force 408 is applied. As shown in FIG. 4, the transmitted pulse 410 may travel in the same direction as the forward pulse 404, and the reflected pulse 412 may travel in the opposite direction as the forward pulse 404. Resistance 402 may represent an equivalent resistance of a part of the electronics module 104 connected to the transmission line sensor 102. It may be set to match the impedance of the transmission line. Similarly, the termination impedance 414 may be matched to the line impedance. While the conductor 204 is shown as the signal carrying line and the conductor 202 is shown as the ground line, it should be noted that in some embodiments the functionality of the two conductors may be switched.

The reflected pulse 412 may be received by the signal processing unit 108 (FIG. 1), or another element of the electronics module 104 configured to receive the reflected pulse 412. The signal processing unit 108 may determine a magnitude of the force 408 on the transmission line sensor 102 or the degree of deformation of transmission line sensor 102 based on the magnitude of the reflected pulse 412. The signal processing unit 108 may determine a location of the force 408 on the transmission line sensor 102 based on a timing of the reflected pulse 412, or a phase of a reflected wave in the case of a stimulus signal 109 that is a continuous wave.

Although the transmission line sensor can sense deformation based on the change in capacitance and/or inductance, in some embodiments the transmission line sensor may sense other properties due to changes in the capacitance and/or inductance. For example, absorption of water by the transmission line sensor may be sensed, as it would cause the capacitance to increase.

In some embodiments, the stimulus signal may be an electrical signal. If the electrical signal has a continuous waveform (e.g., a sinusoidal waveform), the frequency of the electrical signal may be in the microwave frequency range, or at a frequency slightly below the microwave frequency range. The primary frequency component of the signal may be between 1 kHz and 300 GHz, such as between 1 MHz and 300 GHz, for example, between 30 MHz and 300 GHz, such as 30 MHz to 6 GHz, for example.

In some embodiments, a transmission line sensor may be used to sense position in two dimensions by adding a second connection and termination to transmit signals and receive reflections along the vertical dimension of FIG. 2. This allows localizing an applied force in both the horizontal and vertical dimensions of FIG. 2, with one connection being used to measure position along the horizontal dimension and the other connection being used to measure position along the vertical dimension. In such a transmission line sensor, the length l may not be greater than the width w, as they may have the same or similar dimensions.

In embodiments where conductor 202 is a ground plane, it has been appreciated that an exposed signal conductor 204 may allow contact or proximity by an external conductor or high k material (e.g., a finger), to interfere with the measurement. In some embodiments, the signal conductor 204 may be positioned between respective ground planes, which may prevent electrical interaction with the signal conductor 204 by external objects or fields.

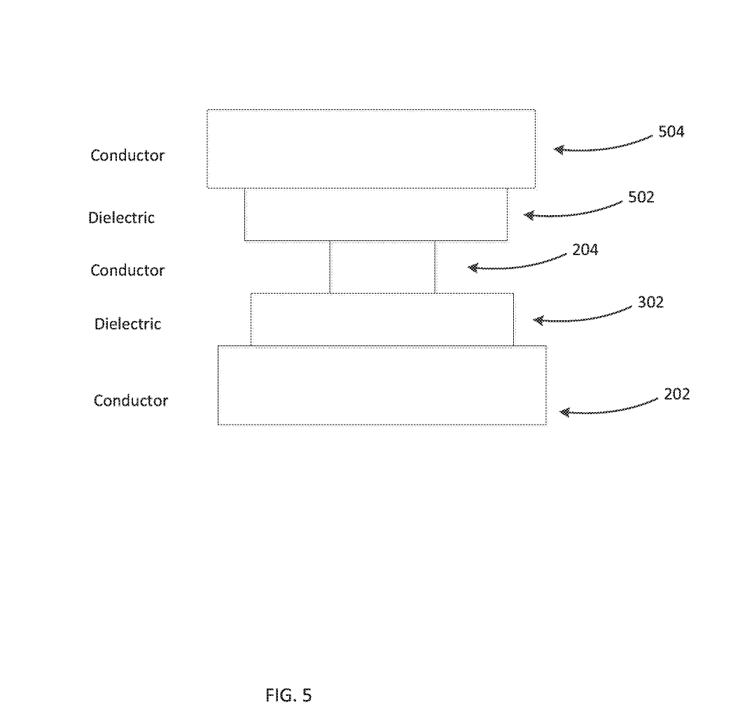

FIG. 5 shows an embodiment of the transmission line sensor 102 in which the signal conductor 204 is positioned between two ground planes. In the embodiment of FIG. 5, the transmission line sensor 102 also includes a second dielectric 502 and third conductor 504 in addition to the conductor 204, dielectric 302 and conductor 202. The second dielectric 502 may separate the conductor 204 and the third conductor 504. The conductor 504 and dielectric 502 may be configured to shield the conductor 204 from direct contact by an outside conductor or proximity by an external high k material, or influence by an external field which may distort the operation of the transmission line sensor 102.

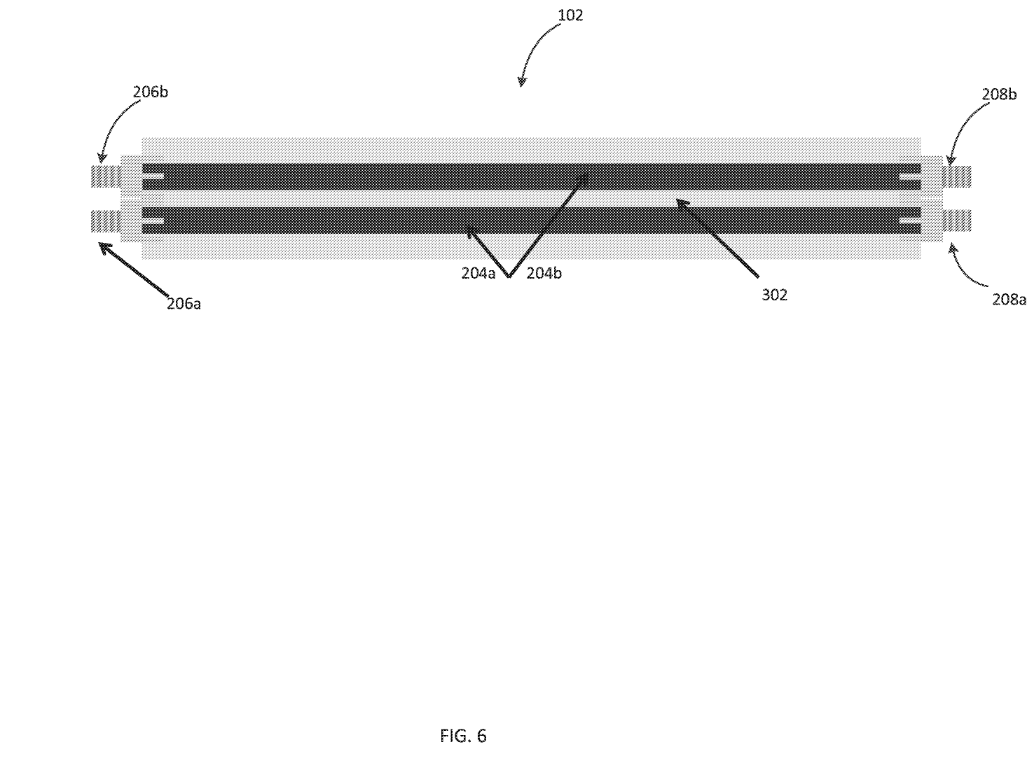

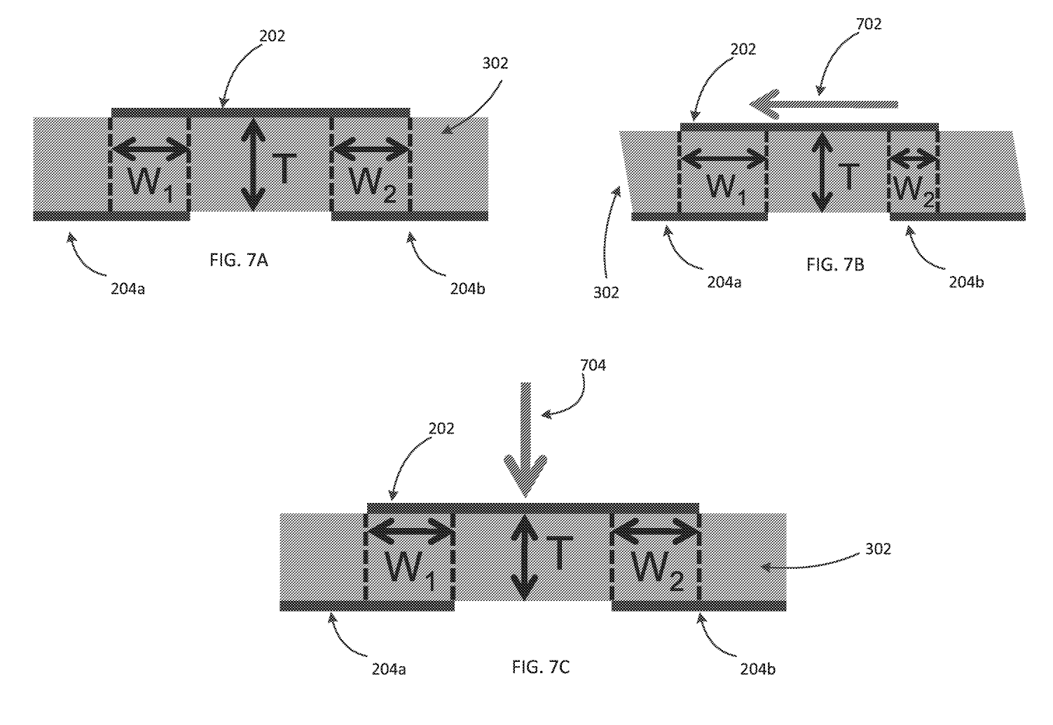

FIG. 6 shows a top view of another embodiment of the transmission line sensor 102 that can measure a shear force. FIGS. 7A-C shows a cross sectional view. The transmission line sensor 102 may comprise a first connector 206a and a second connector 206b, a first termination 208a and a second termination 208b, a conductor 202, a conductor 204a, a conductor 204b, and conductor 202. The first connector 206a may connect the conductor 204a and conductor 202 to the electronics module 104. The second connector 206b may connect the conductor 204b and the conductor 202 to the electronics module 104. The first termination 208a may terminate the first conductor 204a and the second conductor 202. The second termination 208b may terminate the third conductor 204b and the second conductor 202. A dielectric 302 may separate the first conductor 204a and the third conductor 204b from the second conductor 202. The width of the second conductor 202 may be larger than the combined widths of the first conductor 204a and the third conductor 204b.

In FIG. 7A, the second conductor 202 overlaps conductor 204a by a width W1. The conductor 202 overlaps conductor 204b by a width W2. The dielectric 302 between the conductor 202 and conductor 204a and the third conductor 204b has a height of T. In FIG. 7B a shear force 702 is applied across the transmission line sensor 102 on the side of conductor 202. It should be noted that the shear force 702 may be applied across the first conductor 204a and the third conductor 204b in some embodiments, alternatively or additionally. The shear force 702 causes the transmission line sensor to deform, which cause W1 to increase and W2 to decrease proportionally as the second conductor 202 overlaps more with the first conductor 204a and less with the third conductor 204b. The change in widths W1 and W2 caused by the shear force 702 may cause the impedance of the transmission line created by conductor 202 and conductor 204a and the transmission line created by conductor 202 and conductor 204b to both change locally in opposite directions, which produces different reflections on the two transmission lines. The difference between the reflections in the two transmission lines is representative of shear force 702.

Such a configuration may also measure pressure normal to the electrodes 202 and 204. In FIG. 7C a pressure 704 is applied normal to the conductor 202. As dielectric 302 compresses, the height T is reduced. However, the widths W1 and W2 may stay constant relative to the widths shown in FIG. 7A. The compression caused by the pressure 704 may cause the impedance of the transmission line created by conductor 202 and conductor 204a and the transmission line created by conductor 202 and conductor 204b to both change locally in the same direction. The magnitudes of the reflections in the two transmission lines are representative of a normal force 704. In some embodiments, the second conductor 202 may be split into two or more electrically disconnected but mechanically connected conductors, as it is not necessary that conductor 202 be a single conductor.

ΔW ant T can be calculated using the following equations, where W0 is the value of W when the sensor is at rest (no forces applied).

$$G ( x ) = \frac{T ( x )}{W ( x )}$$

$${G}_{1} ( x ) = \frac{T ( x )}{{W}_{0} + Δ W ( x )} , {G}_{2} ( x ) = \frac{T ( x )}{{W}_{0} - Δ W ( x )}$$

$$Δ W ( x ) = \frac{{W}_{0} [ {G}_{2} ( x ) - {G}_{1} ( x ) ]}{{G}_{2} ( x ) + {G}_{1} ( x )} , T ( x ) = \frac{2 {W}_{0} {G}_{2} ( x ) {G}_{1} ( x )}{{G}_{2} ( x ) + {G}_{1} ( x )}$$

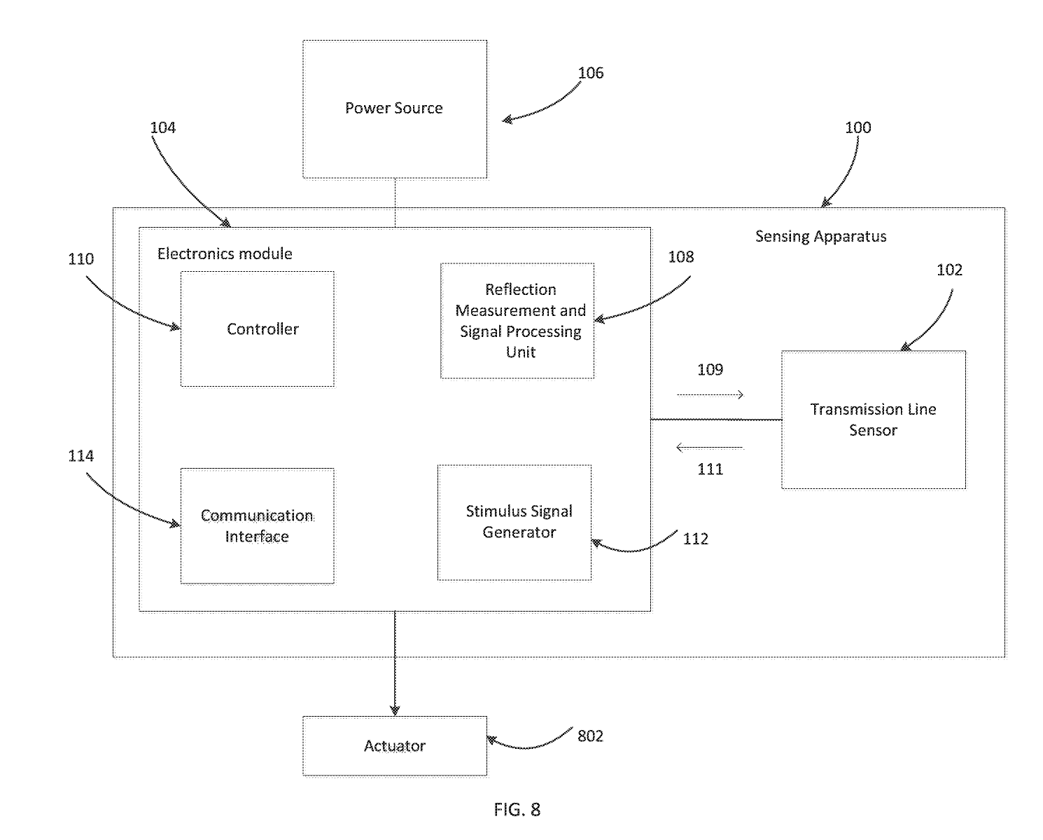

As discussed above, in some embodiments the information obtained from the sensing apparatus 100 may be used to stimulate a sensation in a person to create a sense of touch. FIG. 8 illustrates that the information obtained from the sensing apparatus 100 may be provided to an actuator 802. The actuator 802 may be controlled based on this information. Examples of suitable actuators include vibrational actuators, electrical stimulators, neural implants, etc. The magnitude and/or location of the stimulation produced can depend upon the magnitude and/or location of the force detected by the transmission line sensor 102. This can enable restoring a sense of touch. For example, if a person wears a glove having the transmission line sensor 102 as well as an actuator 802 positioned on the arm, hand, back, or another suitable location with intact natural sense of touch, pressure detected on the glove can be detected and used to control one or more actuators 802 to provide tactile feedback. However, this is not limited to providing tactile feedback for the hand, as such tactile feedback may be provided to any portion of the body.

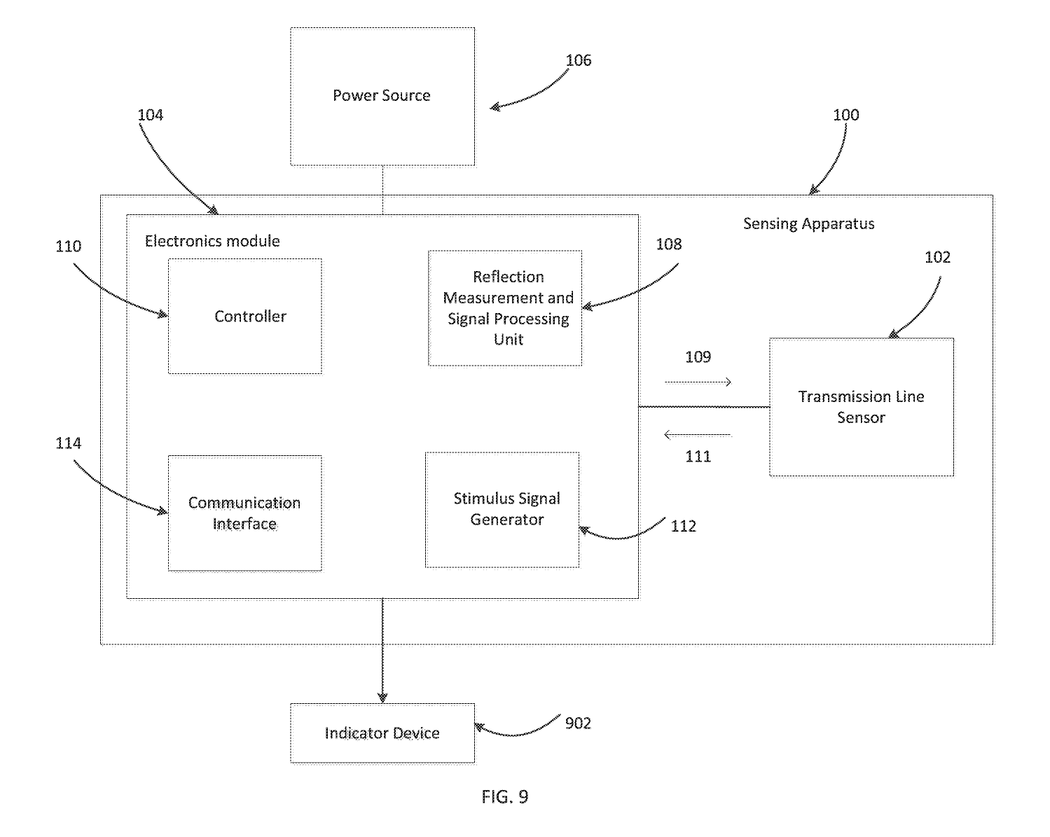

In some embodiments, the information obtained from the sensing apparatus 100 may be used to provide an indication of the duration, intensity and/or location of the sensed pressure. FIG. 9 illustrates that the sensing apparatus 100 may provide information regarding the sensed pressure to an indicator device 902. The indicator device 902 may provide a visual and/or audible indication as to the applied pressure. For example, indicator device 902 may include a display that displays the duration, intensity and/or location of the sensed pressure. This may allow a clinician or a patient to view this information to assist with diagnosing and/or treating a condition. In some embodiments, indicator device 902 may provide a visual and/or audible warning when the duration, intensity and/or location of the sensed pressure exceeds a threshold. For example, the indicator device 902 may provide a warning that the pressure on a portion of the body exceeds an intensity threshold for a time that exceeds a time threshold. This may assist with preventing pressure-related conditions, such as bedsores, or pressure sores in prosthetics for example.

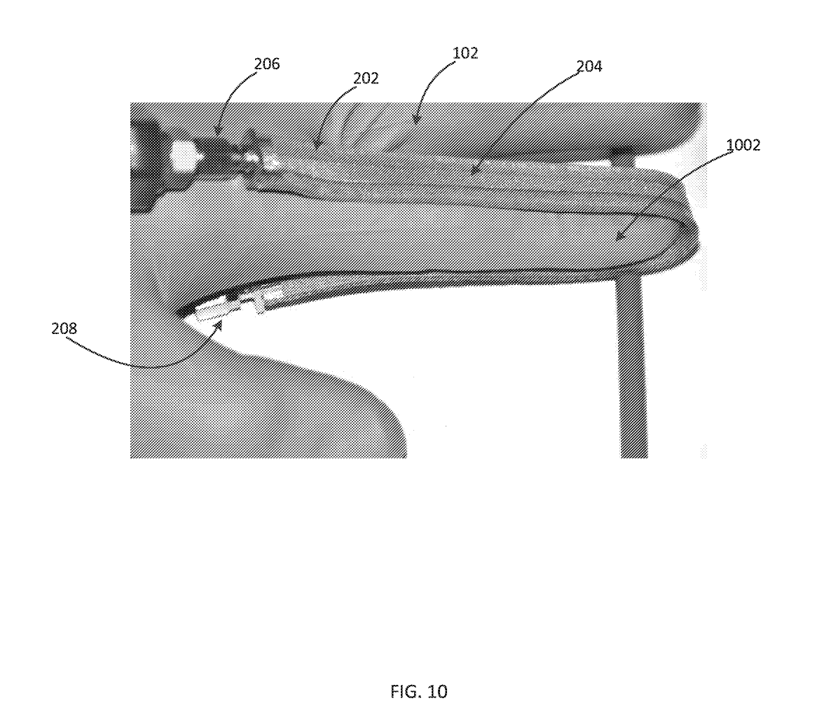

FIG. 10 shows a transmission line sensor 102 being worn on a finger 1002. The transmission line sensor 102 may be wrapped around the finger 1002. The connector 206 may be opposite the termination 208, with the conductors 202 being wrapped around the finger along the length of the finger 1002. In some embodiments, the transmission line sensor 102 may cover only a portion of the finger 1002, or be wrapped horizontally around it instead of vertically along it. The sensing apparatus 100 may detect a force or pressure applied to the finger 1002 along the transmission line sensor 102. Alternatively or additionally, the transmission line sensor can measure, through stretch, the deflection of the fingers or the cupping of the hand. Accordingly, the overall pose of the hand can be detected.

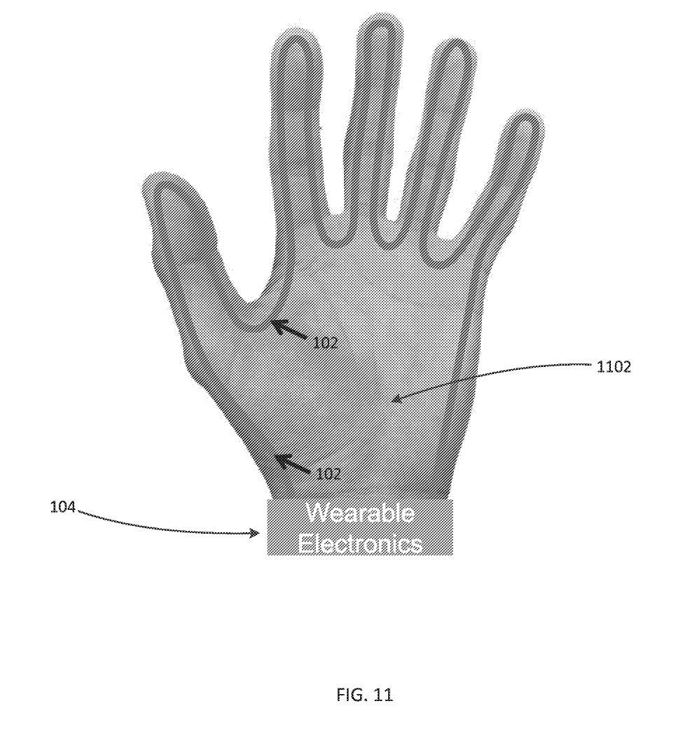

FIG. 11 shows a transmission line sensor 102 wearable on a palm 1102. The transmission line sensor 102 may run along the edge of the palm 1102 as shown, or cover it as a glove. The electronics module 104 may be positioned off of the palm so 1102 that the entire palm may be covered by the transmission line sensor 102, or be positioned on the palm 1102 as required by the application. In some embodiments, multiple sensor modules may run across the palm, or in any configuration suitable to detect a pressure or force on the palm.

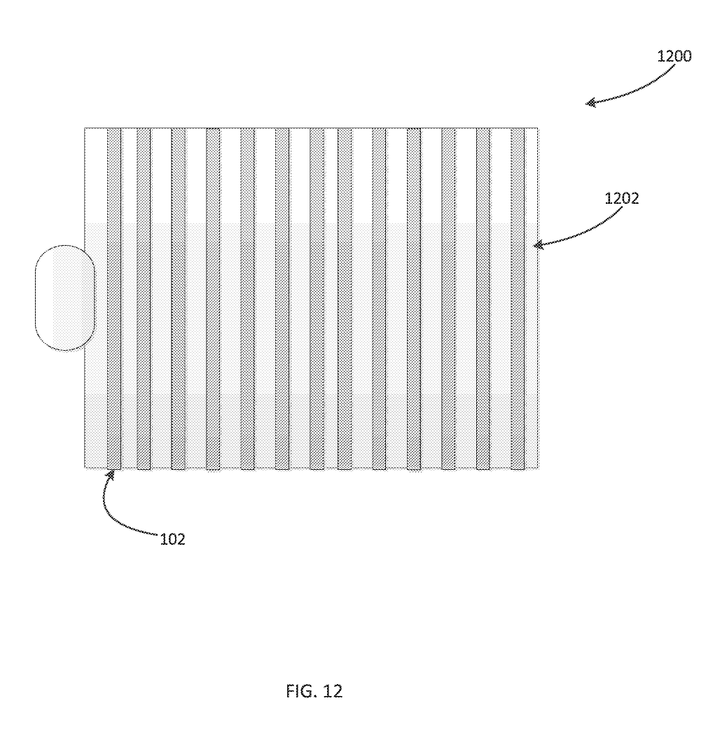

In some embodiments, a flexible transmission line sensor 102 may be incorporated into bedding for the purpose of preventing bed sores, pressure sores, and the like. FIG. 12 shows bedding 1200 with incorporated transmission line sensors 102. The transmission line sensors 102 may be woven into a fitted sheet 1202, secured beneath it, or secured on its surface. The rest of the sensing apparatus 100 may be located on an edge of the fitted sheet 1202, or another location. When a pressure exceeding a threshold has been detected for a predetermined period of time, an alert may be provided to a patient or a clinician, as discussed above with respect to FIG. 9. In some embodiments, the sensing apparatus 100 may be used to monitor sleep patterns and track the position and/or movement of a person in the bedding 1200.

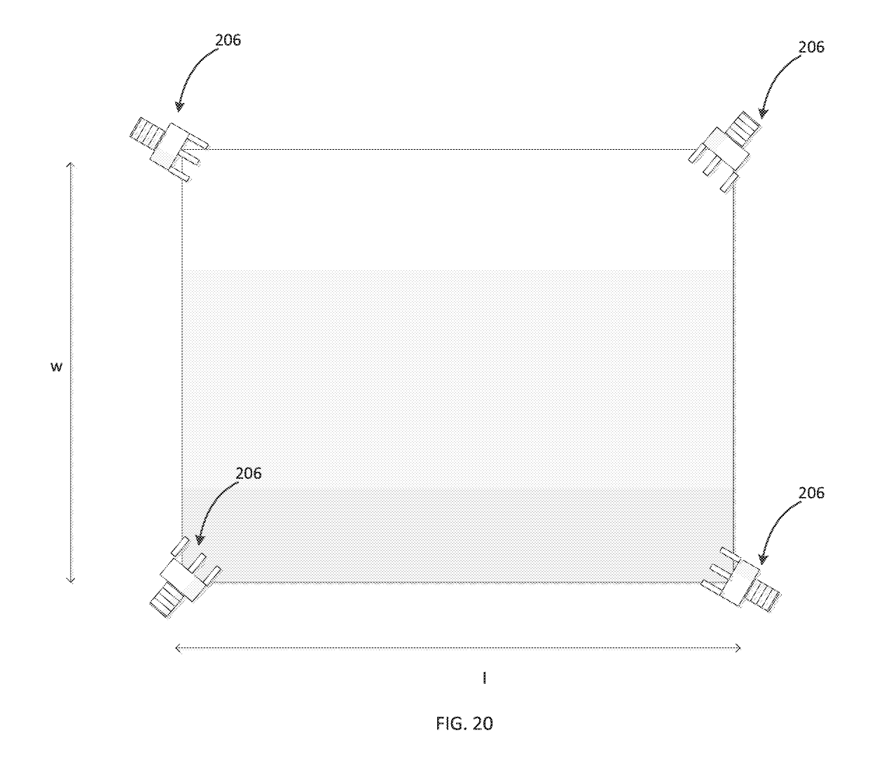

An alternative to using a number of one-dimensional transmission line sensors is to use a two-dimensional transmission line sensor, which can be considered a transmission plane. An example of a two-dimensional transmission line sensor is shown in FIG. 20. For example, the width w may be made very wide, on the order of the length 1. The input/output connectors 206 may be placed in the corners, for example, and the edges of the two-dimensional plane may be terminated with a distributed resistor like 414. The corner transmitters may send out waves and listen for the reflections. The reflections could then be used to “triangulate” the location of the reflecting deflection, and again the amplitudes of the reflections would indicate the magnitude of the reflecting deflection.

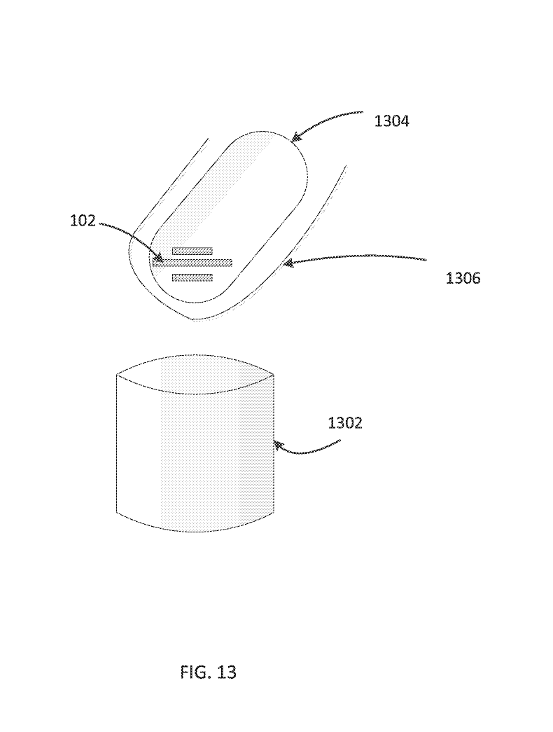

As discussed above, in some embodiments the transmission line sensor 102 may sense the pressure due to a prosthetic. FIG. 13 shows a prosthetic 1302 with a liner 1306 having an incorporated transmission line sensor 102. The transmission line sensor 102 may be woven into the liner 1306, secured beneath it, or secured on its surface. The one or more transmission line sensors 102 may be used to detect a force or pressure exerted between the appendage 1304 and the prosthetic 1302. In some embodiments, only one transmission line sensor may be used. In some embodiments, multiple transmission line sensors may be used. The transmission line sensor(s) 102 may be used to prevent pressure sores or other issues caused by blood flow in an appendage 1304 or an incorrect fitting of the prosthetic 1302.

Other examples of applications in which the transmission line sensor 102 may be used include robotics applications, smart clothing, and smart footwear. In some embodiments, such a sensor may be affixed to an airfoil or hydrofoil to measure pressure on the airfoil or hydrofoil in various operating conditions. Other applications include virtual reality, training, research and animation. Touch-capture gloves incorporating the transmission line sensor 102 may be used to record the forces applied by a person's fingers, which may be used to interact with the virtual environment, or training research or animation environments.

Although a transmission line for electromagnetic signals has been described, the same principles apply to other transmission lines such as optical transmission lines (e.g., waveguides, such as fiber optics) and acoustic transmission lines. In some embodiments, sensing apparatus 100 may use optical or acoustic signals, and the first conductor 204 and second conductor 202 may be any mechanically flexible and/or stretchable material suitable for propagating either optical or acoustic signals.

The electronics module 104 may include a controller, such as controller 110, for performing the steps described above of producing, receiving, and analyzing signals to/from a transmission line sensor. Such a controller may be implemented by any suitable type of circuitry. For example, the controller may be implemented using hardware or a combination of hardware and software. When implemented using software, suitable software code can be executed on any suitable processor (e.g., a microprocessor) or collection of processors. The one or more controllers can be implemented in numerous ways, such as with dedicated hardware, or with general purpose hardware (e.g., one or more processors) that is programmed using microcode or software to perform the functions recited above.

In this respect, it should be appreciated that one implementation of the embodiments described herein comprises at least one computer-readable storage medium (e.g., RAM, ROM, EEPROM, flash memory or other memory technology, or other tangible, non-transitory computer-readable storage medium) encoded with a computer program (i.e., a plurality of executable instructions) that, when executed on one or more processors, performs the above-discussed functions of one or more embodiments. In addition, it should be appreciated that the reference to a computer program which, when executed, performs any of the above-discussed functions, is not limited to an application program running on a host computer. Rather, the terms computer program and software are used herein in a generic sense to reference any type of computer code (e.g., application software, firmware, microcode, or any other form of computer instruction) that can be employed to program one or more processors to implement aspects of the techniques discussed herein. In some embodiments, a configuration memory for an FPGA or CPLD may be used to implement an algorithm without using a microprocessor or computer software.

### EXAMPLE 1

As illustrated in FIG. 4, in some embodiments a high frequency pulse is applied to a transmission line with an impedance discontinuity due to a depression of the dielectric caused by applied pressure. This discontinuity causes a portion of the pulse to be reflected back to the source. Through time domain reflectometry (TDR), the round-trip time-of-flight of the pulse and its amplitude can be used to determine the location and magnitude of the depression and hence the applied pressure. Thus, the transmission line becomes a two-terminal distributed sensor that can be snaked over a two-dimensional area. TDR is a standard technique for finding faults in cables, for example. While it works, TDR may present a few issues. First, if more than one discontinuity is present, the pulse can re-reflect between them causing “ghosts” in the response, which cannot be easily distinguished from genuine responses. Furthermore, a practical distributed pressure sensor will be exposed to continuous gradients of pressure, not discrete points. For these reasons, in some embodiments the simulation and sensing may be performed in the frequency domain. The complex impedance of the transmission line may be measured with a vector network analyzer (VNA) at a plurality of frequencies e.g., in the microwave range. For example, measurements were performed at 201 frequencies from about 30 MHz to about 6 GHz. This data is then processed as described below to reconstruct the applied pressure.

The traditional Telegrapher's Equations are modified to be make the inductance per unit length L(x) and the capacitance per unit length C(x) functions of the position x along the line.

Thus,

$$\begin{matrix}\frac{\partial V ( x , t )}{\partial x} = - L ( x ) \frac{\partial I ( x , t )}{\partial t} & ( 1 ) \\ \frac{\partial I ( x , t )}{\partial x} = - C ( x ) \frac{\partial V ( x , t )}{\partial t} & ( 2 )\end{matrix}$$

where t is time, V(x,t) is voltage and I(x,t) is current.

To solve (1) and (2), several assumptions may be made. First, assume the perturbation in line impedance is small, that is, the line is compressed less than about 10-20% of its thickness. Second, assume the line to be a lossless and properly terminated ideal parallel plate transmission line having length 1 and plate gap spacing g(x). With these assumptions, perturbation analysis yields

$$V ( x , t ) = {V}^{*} {e}^{j ω ( t - \frac{x}{c} )} + \frac{{V}^{*}}{2 {G}_{0}} {e}^{j ω ( t - \frac{x}{c} )} {\int }_{x} \frac{dg ( {x}^{′} )}{dx} {e}^{- 2 j ω \frac{{x}^{′}}{c}} {dx}^{′} \qquad ( 3 )$$

where G₀ is the nominal conductor spacing with the line at rest, g(x) is the perturbed conductor spacing as a function of position along the line, and V* is the amplitude of the wave launched at the terminals at x=0 with phase velocity c and angular frequency co. In (3), the first term is a forward-traveling wave, and corresponds to the 0^{th}-order term in the perturbation series. The second term is a backward-traveling wave that reflects off line depressions, and corresponds to the 1^{st}-order term in the perturbation series. Thus, (1) and (2) are solved to first order in a perturbation parameter that scales g(x)/G₀−1. For S₁₁(ω) defined as the ratio of the backward-traveling wave to the forward-traveling wave at x=0, (3) can be rearranged to yield

$${S}_{11} ( ω ) = \frac{1}{2 {G}_{0}} {\int }_{0}^{l} \frac{dg ( {x}^{′} )}{dx} {e}^{2 j ω \frac{{x}^{′}}{c}} {dx}^{′} \qquad ( 4 )$$

where l is the length of the line and all other variables have been previously defined. S₁₁(ω) may be measured experimentally.

It is now desired to recover g(x) from S₁₁(ω). To do so, observe that (4) is essentially a Fourier transform that can be inverted. Inversion is carried out numerically using a sampled measurement set. This results in

$$\frac{dg}{dx} = \frac{4 {N}^{*} {G}_{0} {f}_{0}}{c} IFFT [ {S}_{11} ( f ) ] \frac{1}{α} \qquad ( 5 )$$

where ƒ=2πω is circular frequency, ƒ₀ is the frequency sample step size, and c is the phase velocity in the transmission line which is slower than the speed of light by the velocity factor of the line. N* is the number of data points after the S₁₁(f) measurement set has been made Hermitian so as to have a purely real inverse transform. This is accomplished by combining it with its complex conjugate and adding a DC reflection coefficient, which is assumed to be zero. The resulting measurement set has a length of N*=2N+1 where N was the number of measured frequency points. The parameter a is defined as G/Z·dZ/dG where Z is the impedance of the line and G is the gap. For an ideal parallel plate transmission line α=1 but due to the effects of fringing fields α is less than 1 for a real transmission line. Using the equations for the impedance of a real strip line transmission line and the dimensions of the actual line, a value of α=0.8 is derived.

Integrating (5) yields a reconstruction of the deformation of the transmission line gap as a function of position. Pressure is then calculated using the Young's modulus of the dielectric.

The distance between position data points ΔX=c/(2N*ƒ₀) so the resolution of the sensor is limited by the shortest propagating wavelength. Thus, the resolution can be improved by either increasing the excitation frequency or decreasing the propagation speed. The frequency may be limited to about 6 GHz by loss and reflection due to manufacturing tolerances, but the wave speed can be decreased by increasing the dielectric constant of the PDMS dielectric. This may be achieved by adding a high-κ ceramic material (e.g., CCTO), to the dielectric material

The sensor can be manufactured with simple molding techniques that can be easily scaled to arbitrarily large areas, as opposed to with lithographic techniques, which are generally limited by wafer sizes. The completed sensors remained stretchable and flexible. An example of a manufacturing process is as follows.

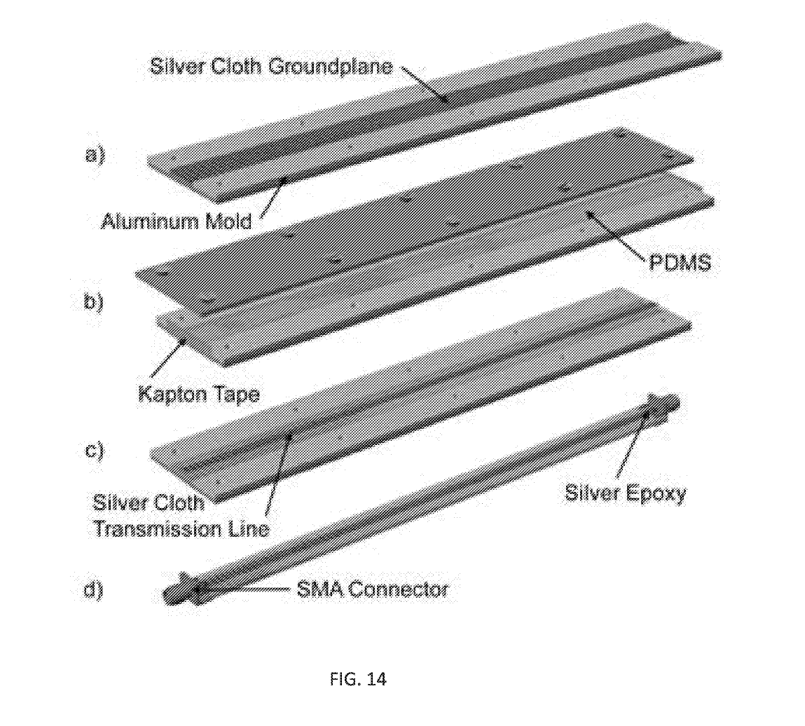

First, Polydimethylsiloxane (PDMS, Sylgard® 184) is mixed with 10% linker and optionally CCTO powder in a centrifugal mixer. Next a piece of stretchable silver cloth, Statex Shieldex® MedTex™ P-130 is cut to be slightly larger than the finished line, soaked in pure PDMS and clamped in the mold. Before soaking, two small pieces of Kapton® tape are used to protect the back of this cloth from the PDMS where the SMA connectors will attach. The mold is then placed in a vacuum chamber until all air is removed. It is then cured in an oven at 120° C. for 20 minutes. With the mold thus prepared, it is filled with PDMS (optionally doped with CCTO powder) to form the dielectric. Again it is degassed; the cover is bolted onto it, and it is again cured. Next, another piece of silver cloth is protected with Kapton® and then precisely cut into a 4.1-mm-wide strip, calculated to achieve a resting impedance of 50 Ω. After being soaked in pure PDMS, this strip is adhered to the top of the dielectric, tape side up. The lid is then replaced on the mold and it is cured one final time. Finally, the mold is disassembled, the excess silver cloth ground plane is cut off, and SMA connectors are attached to either end with MG Chemicals MG-8331 conductive silver epoxy. This process is illustrated in FIG. 14. In FIG. 14a the silver cloth for the ground plane is soaked in PDMS, mounted in the mold and cured. In FIG. 14b the mold is filled with PDMS (optionally doped with CCTO), the cover is attached, and the PDMS is cured. In FIG. 14c The silver cloth transmission line soaked in PDMS and protected with Kapton® tape is installed and cured. In FIG. 14d The line is removed from the mold, the tape is removed, the excess silver cloth ground plane is trimmed and the SMA connectors are installed with conductive silver epoxy.

For testing, one end of the line end was connected to Port 1 of an HP 8410C vector network analyzer (VNA) with a flexible phase stable test port extension cable; the other end was terminated by a 50 Ω microwave terminator.

The network analyzer was connected to a computer running a real-time version of the algorithm described above that allows the effects of depressing the line to be seen immediately. The software can also perform base-line subtraction on the collected data. This can compensate for imperfections in line fabrication that result in permanent impedance discontinuities that would otherwise appear in the data. The baseline is subtracted after the line is inserted into the test apparatus and after the apparatus has been set to just begin depressing the line. This has the benefit of also subtracting off any effect due to the proximity of the testing apparatus which is applying pressure to the line to the line.

To measure the position at which pressure was applied, the line was marked with a ruler and pressure was applied at the marked points.

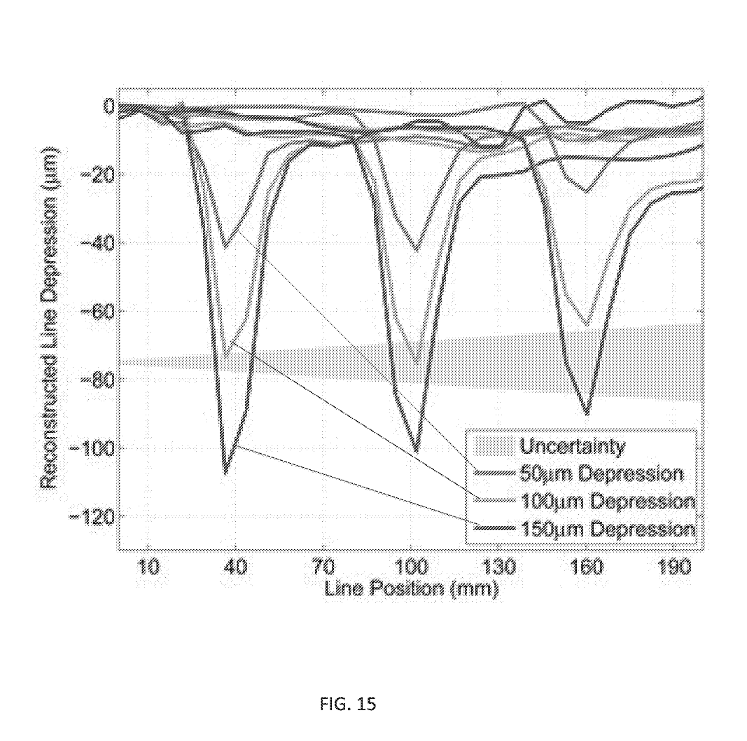

The sensor is very accurate in position, as position accuracy is affected only by the velocity factor of the line and the frequency accuracy of the VNA. FIG. 15 shows the response of the line to depressions made at 40 mm, 100 mm and 160 mm beyond the calibration plane of the VNA. In each case the response is accurate to within the spacing of one data point (7.3 mm for pure PDMS at 6 GHz). In this reconstruction a velocity factor of 0.585 was used, which matches the value of 0.584 found by directly measuring the propagation delay of the line with the VNA. Thus, the reconstruction appears to be quite accurate with regard to position.

As seen in FIG. 15 the depths of the depressions applied 40 mm from the start of the line are reconstructed to within 30% of their actual values. The discrepancy is believed to result from inaccuracy in the a parameter, which was calculated assuming a lossless transmission line. Indeed, experiments with a low-loss line made with copper foil conductors show agreement with theory at 40 mm to within 6%. The response drops off more at positions farther away from the start of the line. This is primarily due to loss in the transmission line; from end to end it has a total resistance of 15 Ω due to the resistance of the silver cloth, which causes loss.

A second effect seen in the data is that the depression settles to a value less than zero for positions along the line beyond the deformed region. This effect has been demonstrated through experiment and simulation to be due primarily to the resistance of the cloth decreasing locally where pressure is applied.

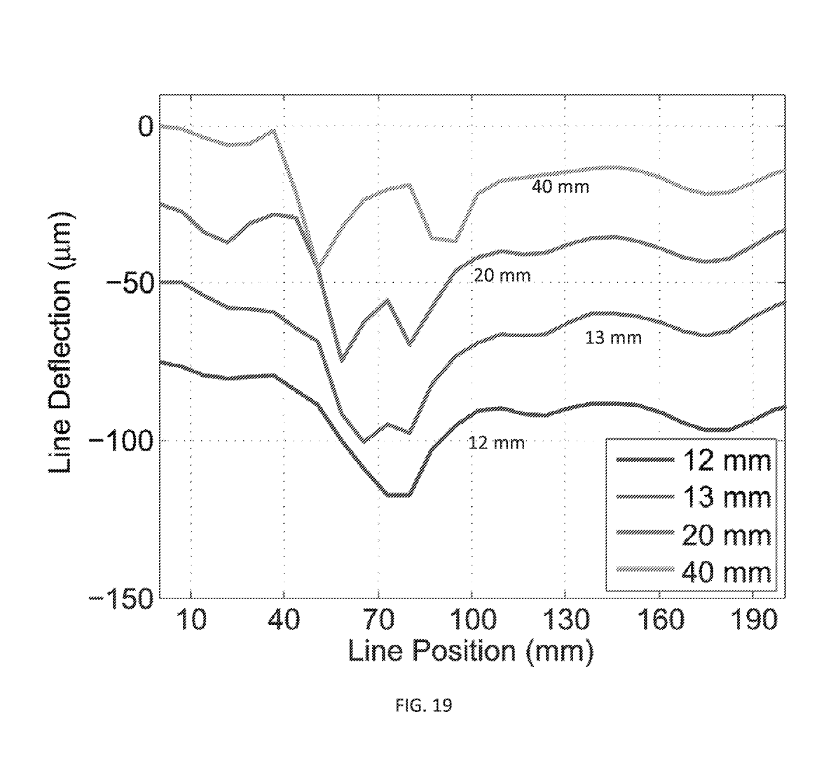

A third source of error is observed for narrowly deflected regions, narrower than a wavelength, for which the response is dramatically decreased. Experiments with simulated data that is otherwise free from error show that the response to depressions having a 10-mm and 4-mm width drops to 80% and 33% of normal, respectively. This effect is shown in FIG. 19.

Finally, note that the experimental uncertainty in FIG. 15 increases with position along the line due to cumulative error in the integral used to reconstruct the depression. See Equation (4).

The resolution is the distance between two discrete depressions at which they can no longer be distinguished from a single depression. To measure resolution, the sensor was depressed at two points with a constant force (from a weight) and these points were gradually brought together until the response from the sensor showed just one depression. At this point the distance between the points was measured with a ruler and recorded as the resolution.

FIG. 19 is a plot showing the resolution measurement. The measured resolution is 12 mm since that is the spacing at which the peaks converge. Curves have been staggered by 50 μm for clarity.

The resolution (and the distance between individual position data points) of the sensor is limited by the size of the shortest wavelength used to excite it. Wavelength can be decreased by increasing the frequency, but the usefulness of increasing frequency is limited by the high frequency loss in the line. Wavelength can also be decreased by decreasing the velocity factor of the line which, can be achieved by adding high-κ ceramic particles, such as CCTO to the PDMS.

Table 1 lists the resolutions and velocity factors for sensors made with five different concentrations of CCTO. From the velocity factor, the wavelength at 6 GHz was also computed. From this data two conclusions can be reached. First, the resolution of the sensor can indeed be increased by adding CCTO to the PDMS. The effect is to increase resolution by about 20%. Second, the minimum discernable resolution is consistently approximately half a wavelength and tracks with velocity factor demonstrating that the resolution limitations of the sensor are due to the wavelength of the propagating wave.

TABLE 1
Resolution as a function of CCTO concentration

| CCTO | | | |
|---|---|---|---|
| Concentration | Resolution | Velocity | Resolution/ |
| (%) | (mm) | Factor | Wavelength |
| 0.00 | 12 ± 1 | 0.584 ± 0.003 | 0.411 ± .036 |
| 6.31 | 12 ± 1 | 0.528 ± 0.003 | 0.455 ± .041 |
| 10.2 | 12 ± 1 | 0.476 ± 0.003 | 0.505 ± .046 |
| 15.4 | 11 ± 1 | 0.456 ± 0.003 | 0.482 ± .047 |
| 20.3 | 9 ± 1 | 0.403 ± 0.003 | 0.447 ± .053 |

Due to the geometric complexity of deforming a line with an arbitrarily shaped object, the relationship between deformation and applied pressure is complex. However, assuming the general shape of the line to be an elastic sheet, and that this geometry results in the PDMS behaving locally as an ideal spring, and further assuming that the Young's modulus of the sensor is equal to that of pure PDMS, ˜500 kPa, (the material becomes harder with added CCTO), the 10 kPa pressure sensitivity of human skin would result in a 37 μm depression, which could easily be detected by the sensor. Thus, the device has a sensitivity approaching that of human skin.

The distributed microwave pressure sensor for tactile skins shows much promise. The resulting sensors are very simple to manufacture, flexible, stretchable, and quite durable. The sensors achieve a depression accuracy of 30% and a position accuracy of 7.3 mm for the pure PDMS sensor. The resolution and position accuracy can be increased by adding CCTO to the PDMS. The overall pressure sensitivity of the device approaches that of human skin.

### EXAMPLE 2

Flexible and stretchable tactile pressure sensors based on distributed microwave sensing technology offer an alternative to traditional arrays of capacitive or resistive sensors. The location and degree of applied pressure is determined from measured reflections in a microwave transmission line. This approach allows for a rugged wide-area sensor that is easily and inexpensively fabricated, and which needs only a single two-conductor connection to external electronics. Here we disclose an improved microwave tactile sensor, offering higher sensitivity and immunity from erroneous readings caused by contact with conductors and/or dielectrics.

The sensor discussed in EXAMPLE 1 has the signal conductor of the transmission line exposed, which may cause erroneous readings if a conductive or dielectric material is brought in contact with it. In this example we demonstrate a fully shielded device that also offers higher sensitivity.

The microwave tactile sensor includes a single microwave transmission line with a soft, deformable dielectric. When pressure is applied to this line, it is deformed, changing the spacing between the ground plane and center conductor and creating a local impedance discontinuity. Conceptually, this discontinuity causes a portion of the fast rise-time pulse applied to the transmission line to be reflected back to the source.

To recover the dielectric thickness of the transmission line, g(x), from the reflection coefficient measured by the VNA at the beginning of the line, S₁₁(ω), equation (1) is used where

$$\frac{dg}{dx} = \frac{4 {N}^{*} {G}_{0} {f}_{0}}{c} IFFT [ {S}_{11} ( f ) ] \frac{1}{α} \qquad ( 1 )$$

ƒ=2πω is circular frequency, ƒ₀ is the frequency sample step size, and c is the phase velocity in the transmission line, which is slower than the speed of light by the velocity factor of the line. N* is the number of data points after the S₁₁(ƒ) measurement set has been made Hermitian so as to have a purely real inverse transform and is equal to 2N+1 where N was the number of measured frequency points. The parameter α is defined as G/Z·dZ/dG where Z is the impedance of the line and G is the gap. For an ideal parallel plate transmission line “α=1” but due to the effects of fringing fields, “α” is less than 1 for a real transmission line. Using the equations for the impedance of a real stripline transmission line and the actual dimensions, a value of α=0.76 is derived. The distance between position data points is ΔX=c/(2N*ƒ₀) so the resolution of the sensor is limited to about half the shortest propagating wavelength.

As discussed in EXAMPLE 1, the sensors can be manufactured with simple molding techniques that can be easily scaled to arbitrarily large areas, as opposed to with lithographic techniques, which are generally limited by wafer sizes. The completed sensors remained stretchable and flexible. As compared to EXAMPLE 1, the pressure sensitivity of the sensor was increased because NuSil® R-2188 is softer than PDMS (Durometer A-17 vs A-43). The same silver cloth, Statex Shieldex® MedTex™ P-130 is used for the line and shield. The width of the transmission line center conductor, 4.1 mm, was used to achieve a compromise between low line resistance and achieving a resting impedance near 50 Ω.

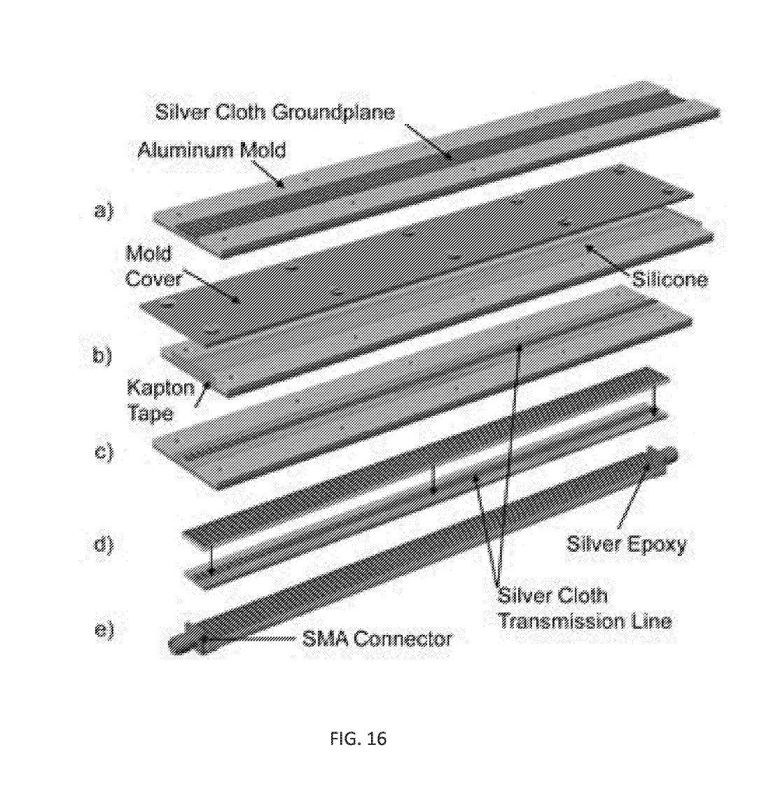

FIG. 16 shows a fabrication diagram for transmission line pressure sensor. In FIG. 16a the silver cloth for the ground plane is mounted in the mold, coated in NuSil® R-2188 silicone, vacuum degassed and cured. In FIG. 16b the mold is filled with silicone, degassed again, covered and cured. In FIG. 16c the silver cloth transmission line soaked in silicone and protected with Kapton® tape is installed and cured. In FIG. 16d steps a) and b) are repeated to make a second cloth/silicone structure. This piece is laminated with more silicone over the top of the line. In FIG. 16e SMA connectors are attached to the completed line with conductive silver epoxy

For testing, one end of the line is connected to Port 1 of an HP 8410C vector network analyzer (VNA) with a flexible phase-stable test port extension cable; the other end is terminated by a 50 Ω microwave terminator. Note that the sensor measures deformation, which can be related to pressure by the Young's modulus of the sensor material and appropriate mechanical modeling. The network analyzer is connected to a computer, which runs the algorithm described by (1) and plots the output in real time. A baseline is subtracted from the data after the line is inserted into the test apparatus and after the apparatus has been set to just begin depressing the line. To measure the position of the deformation, the line is marked with a ruler and pressure is applied at the marked points.

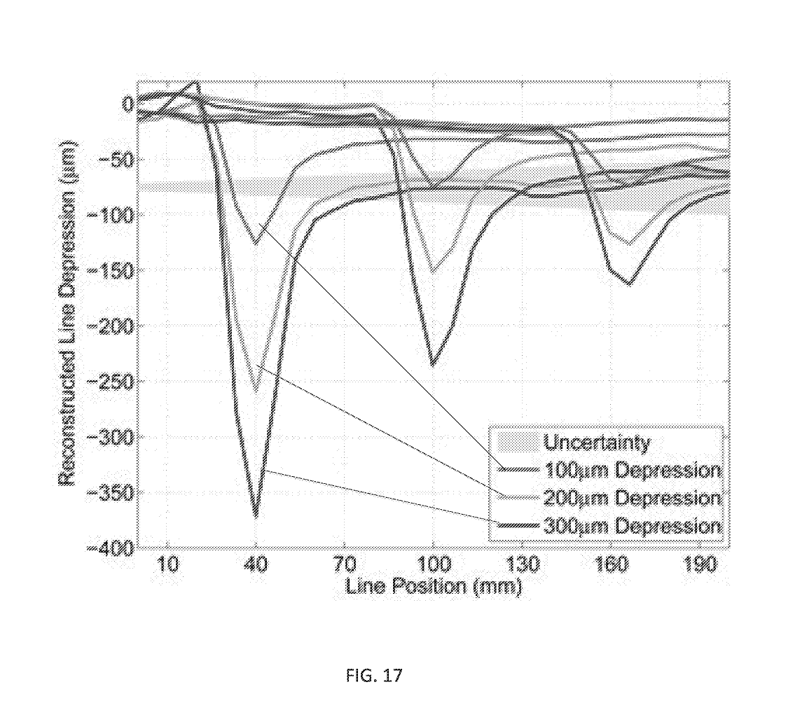

As seen in FIG. 17, the depths of the depressions applied 40 mm from the start of the line are reconstructed to within 30% of their actual values. The discrepancy is believed to result from inaccuracy in a, which was calculated assuming a lossless stripline transmission line per. In EXAMPLE 1, a similar reconstruction for a microstrip transmission line yielded a result that underpredicted the actual depression by about 30%. However, in both cases the discrepancy can be much improved by adjusting the a value. For example, in this example, setting a to a value of 0.96 yields a reconstruction within 3% of the actual value for all depressions at 40 mm.

In the reconstruction, the depression settles to a value less than zero for positions along the line beyond the deformed region. This effect has been demonstrated through experiment and simulation to be due primarily to the local piezoresistive decrease in cloth resistance where pressure is applied.

Note that for narrowly deflected regions, narrower than a wavelength, the response is dramatically decreased. Experiments with simulated data that is otherwise free from error show that the response to depressions having a 10 mm and 4 mm width drops to 80% and 33% of normal, respectively.

Finally, note that the experimental uncertainty in FIG. 17 increases with position along the line due to cumulative error in the integral used to reconstruct the depression. See (1).

The major improvement in this device as compared to that in EXAMPLE 1 is that, with the addition of a second ground plane, the transmission line is now insensitive to erroneous readings due to contact with conductors or proximity to high-k materials such as a hand.

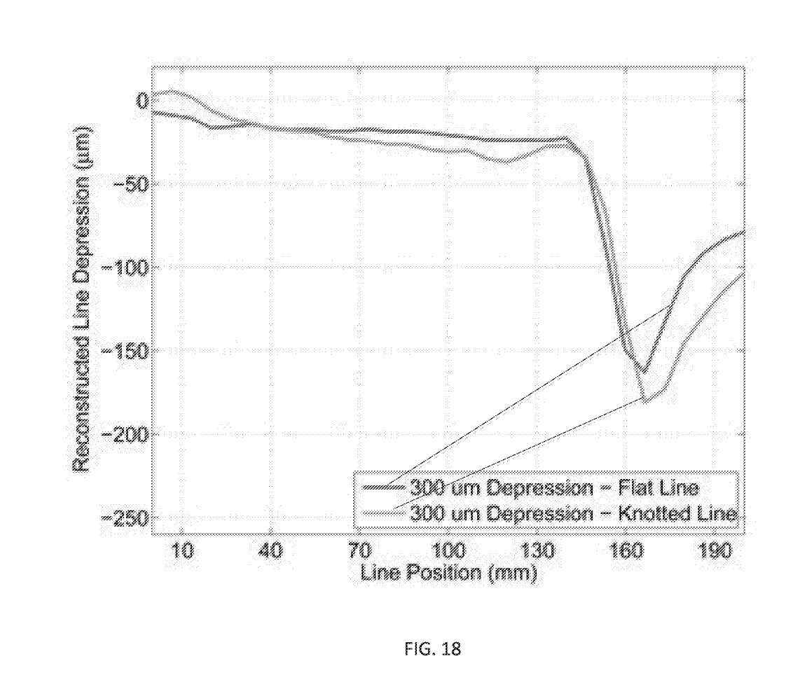

As a demonstration of the truly flexible and stretchable nature of this sensor technology, a 300 μm depression at 160 mm was measured both with the sensor lying flat on a table and with the sensor tied in a knot between the VNA and the location of the deformation as shown in FIG. 18. Note that the subtracted baseline was updated after the knot (the minimum radius of curvature is about 6 mm) was tied. FIG. 18 shows the remarkable agreement between the measurements.

Microwave transmission line based tactile sensors offer advantages over array based devices in terms of simplicity, durability, and minimum connections. This work demonstrates the practicality of such a device, with shielding to assure insensitivity to external fields, and operation in a tight radius of curvature.

Various aspects of the apparatus and techniques described herein may be used alone, in combination, or in a variety of arrangements not specifically discussed in the embodiments described in the foregoing description and is therefore not limited in its application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. An apparatus, comprising:
a transmission line sensor that is mechanically flexible and/or stretchable, the transmission line sensor including:
a first conductor;
a second conductor; and
a dielectric between the first conductor and the second conductor;
an electronics module configured to:
transmit a first signal along the transmission line sensor;
receive a second signal from the transmission line sensor; and
analyze the second signal to determine information regarding deformation of the transmission line sensor caused by a force applied to the transmission line sensor.

2. The apparatus of claim 1, wherein the deformation comprises compression of the transmission line sensor.

3. The apparatus of claim 1, wherein the second signal is reflected from a location of the deformation.

4. The apparatus of claim 1, wherein the electronics module is configured to determine a location of the deformation.

5. The apparatus of claim 1, wherein the electronics module is configured to determine a magnitude of the deformation or a magnitude of the force.

6. The apparatus of claim 1, wherein the electronics module is configured to determine a location of the deformation by detecting a timing or phase shift of the second signal with respect to the first signal.

7. The apparatus of claim 1, wherein the electronics module is configured to determine a magnitude of the deformation or the force by detecting a magnitude of the second signal.

8. The apparatus of claim 1, wherein the first signal is a pulsed signal or the first signal has a continuous waveform.

9. (canceled)

10. (canceled)

11. The apparatus of claim 1, wherein the first conductor comprises conductive cloth, the second conductor comprises conductive cloth, or both the first conductor and the second conductor comprise conductive cloth.

12. The apparatus of claim 1, wherein the dielectric comprises a polymer.

13. (canceled)

14. (canceled)

15. (canceled)

16. (canceled)

17. (canceled)

18. The apparatus of claim 1, wherein the dielectric is compressible in response to the force.

19. (canceled)

20. (canceled)

21. (canceled)

22. The apparatus of claim 1, wherein the force is a shear force.

23. The apparatus of claim 1, wherein the transmission line sensor further comprises a third electrode on a same side of the dielectric as the second electrode and the electronics module is configured to detect the second signal from the second electrode and a third signal from the third electrode.

24. The apparatus of claim 23, wherein the electronics module is configured to detect a shear force or displacement based on the second signal and the third signal.

25. The apparatus of claim 24, wherein the electronics module is configured to calculate a shear force based on a difference between the second signal and the third signal.

26. (canceled)

27. (canceled)

28. (canceled)

29. (canceled)

30. (canceled)

31. A transmission line sensor that is mechanically flexible and/or stretchable, the transmission line sensor comprising:
a first conductor;
a second conductor; and
a dielectric between the first conductor and the second conductor, the dielectric being compressible in response to an applied force to cause a change in impedance at a location at which the dielectric is compressed that reflects an incident electrical signal in a frequency range of 1 kHz to 300 GHz.

32. The transmission line sensor of claim 31, wherein the first conductor comprises conductive cloth, the second conductor comprises conductive cloth, or both the first conductor and the second conductor comprise conductive cloth.

33. The transmission line sensor of claim 31, wherein the dielectric comprises a polymer.

34. (canceled)

35. (canceled)

36. (canceled)

37. (canceled)

38. (canceled)

39. The transmission line sensor of any preceding claim 31, wherein the transmission line sensor is a two-dimensional transmission line sensor.

40. A method of operating a sensing apparatus comprising a transmission line sensor, the transmission line sensor including, a first conductor, a second conductor, and a dielectric between the first conductor and the second conductor, the method including:
transmitting a first signal along the transmission line sensor;
receiving a second signal from the transmission line sensor in response to the first signal; and
analyzing the second signal to determine information regarding deformation of the transmission line sensor caused by a force applied to the transmission line sensor.

41. An apparatus, comprising:
a transmission line sensor that is mechanically flexible and/or stretchable, the transmission line sensor including a transmission line; and
an electronics module configured to:
transmit a first signal along the transmission line sensor;
receive a second signal from the transmission line sensor; and
analyze the second signal to determine information regarding deformation of the transmission line sensor caused by a force applied to the transmission line sensor.

42. (canceled)
